(19) United States
(12) Patent Application Publication
(10) Pub. No.: US 2023/0048278 A1
(43) Pub. Date: Feb. 16, 2023

(54) NEUROMORPHIC HARDWARE APPARATUS BASED ON A RESISTIVE MEMORY ARRAY

(71) Applicants: HYUNDAI MOTOR COMPANY, Seoul (KR); KIA CORPORATION, Seoul (KR); POSTECH RESEARCH AND BUSINESS DEVELOPMENT FOUNDATION, Pohang-si (KR)

(72) Inventors: Su-Jung Noh, Seoul (KR); Ji-Sung Lee, Suwon-si (KR); Han-Saem Lee, Seoul (KR); Joon-Hyun Kwon, Hwaseong-si (KR); Hyun-Sang Hwang, Daegu (KR); Woo-Seok Choi, Hanam-si (KR)

(73) Assignees: HYUNDAI MOTOR COMPANY, Seoul (KR); KIA CORPORATION, Seoul (KR); POSTECH RESEARCH AND BUSINESS DEVELOPMENT FOUNDATION, Pohang-si (KR)

(21) Appl. No.: 17/571,255

(22) Filed: Jan. 7, 2022

(30) Foreign Application Priority Data
Aug. 12, 2021 (KR) 10-2021-0106567

(51) Int. Cl. G11C 13/00; G11C 11/54; G11C 7/06; G11C 7/16

(52) U.S. Cl. CPC G11C 13/004; G11C 13/0069; G11C 13/0038; G11C 11/54; G11C 7/062; G11C 7/16

(57) ABSTRACT

A neuromorphic hardware apparatus based on a resistive memory array includes a resistive memory array in which a plurality of synaptic resistor elements are arranged. Each synaptic resistor element is changed in its resistance value depending on a voltage pulse applied thereto and stores the resistance value for a predetermined time. The apparatus also includes a neuron circuit configured to receive an output signal from the resistive memory array and to output a voltage signal to another resistive memory array. The neuron circuit includes a temperature compensation unit, which compensates for an output voltage of the resistive memory array on the basis of an operating temperature of the resistive memory array. Even when a resistive memory array outputs an abnormal output depending on an operating temperature, by compensating a neuron circuit for an input value, it is possible to prevent an operation error from occurring.

### CROSS-REFERENCE TO RELATED APPLICATION

This application claims priority to Korean Patent Application No. 10-2021-0106567, filed on Aug. 12, 2021, the content of which is incorporated herein by reference in its entirety.

### BACKGROUND OF THE DISCLOSURE

### Field of the Disclosure

The present disclosure relates to an apparatus capable of forming an artificial neural network by a resistive memory array and a neuron circuit.

### Description of Related Art

An artificial neural network is a network for imitating and learning the processing of information in the human brain. In order to implement this network, the artificial neural network comprises a neuron circuit and a resistive memory array.

A resistive RAM is a kind of next generation nonvolatile memory and is a device having memristor properties. The memristor, as a compound word of a memory and a resistor, has resistance properties, does not have a constant resistance value, varies in the resistance value thereof depending on a specific voltage pulse applied to both ends thereof, and is able to store a varied resistance value for a predetermined time. As resistive RAMs are configured as a crossbar-shaped array, it is possible to function as a synapse element connected between neurons.

However, in terms of the operation of a hardware neural network based on resistive memory arrays, a conductance of a resistive element significantly varies depending on a temperature.

FIG. 3 is a diagram illustrating a measured value Mea. in which a conductance G of a resistive element follows the Arrhenius equation depending on a temperature. Here, a temperature variation that may occur in one resistive element of a resistive memory array used in the neural network hardware may be seen.

FIG. 4 is a cumulative probability graph for conductance, depending on a temperature variation, of resistive elements having a specific resistance value in an array as shown. FIG. 4 illustrates simulation data obtained by applying a temperature variation model measured in a single element. Temperature variations that all cells with the same specific resistance value in a 1 k-bit array may have are plotted using a cumulative distribution function (CDF). In this way, when all elements with the specific resistance value in the array have the temperature variations, a problem may be caused even in the operation of the array.

In other words, as shown in FIG. 5, it may be seen that the probability distribution function (PDF) of a current as the output of a resistive memory array abnormally increases depending on a variation in operating temperature.

The simulation data shows the abnormal operation of the array output current caused due to a variation in the conductance of a resistive element in the array and illustrates a current outputted from a specific output column line, as a distribution function for 10,000 tests in an array inference operation.

Unlike a narrow distribution at 293K (a normal operation at a room temperature), it may be seen that an output current ΣVG also goes out of a normal operating region due to a temperature variation as a temperature rises (an abnormal operation).

In order to cope with this problem, there is a circuit for compensating for a temperature variation of a resistive memory array, as disclosed in Korean Patent Application Laid-Open No. 10-2017-0134444.

However, such a conventional art does not compensate for an output varied depending on a temperature variation. The conventional art is nothing but a post-compensation that changes an input value applied to a resistive memory array with a voltage compensation value. Therefore, such a conventional art has limitations in that it is nothing more than a post-supplementation and accurate compensation cannot be performed.

The contents described in the above Description of Related Art are to aid understanding of the background of the present disclosure and may include what is not previously known to those having ordinary skill in the art to which the present disclosure pertains.

### SUMMARY OF THE DISCLOSURE

An embodiment of the present disclosure is directed to a neuromorphic hardware apparatus based on a resistive memory array. In the neuromorphic hardware apparatus, even when a resistive memory array outputs an abnormal output depending on an operating temperature, an input value for a neuron circuit is compensated for, thereby preventing an operation error from occurring.

In accordance with an embodiment of the present disclosure, a neuromorphic hardware apparatus based on a resistive memory array includes a resistive memory array in which a plurality of synaptic resistor elements are arranged. Each synaptic resistor element is changed in its resistance value depending on a voltage pulse applied thereto and stores the resistance value for a predetermined time. The neuromorphic hardware apparatus also includes a neuron circuit configured to receive an output signal from the resistive memory array and output a voltage signal to another resistive memory array. The neuron circuit includes a temperature compensation unit which compensates for an output voltage of the resistive memory array on the basis of an operating temperature of the resistive memory array.

In addition, the resistive memory array is arranged in the form of a crossbar array and the temperature compensation unit is connected to an output terminal of each column of the resistive memory array.

Here, the temperature compensation unit includes a transimpedance amplifier (TIA), which performs amplification by converting a current signal into a voltage signal.

In addition, a feedback resistor of the transimpedance amplifier is an element, which has the same property as operating property of the resistive memory array depending on a temperature, by having a value according to the following equation.

$${R}_{F} ( T ) = \frac{{R}_{0}}{α ( T )}$$

In this equation, R_{F}(T) is a feedback resistance value at the operating temperature, Rₒ is an initial resistance value of the feedback resistor at a room temperature, and α(T) is a set value based on operating temperature data of the feedback resistor.

Meanwhile, the neuron circuit includes an ADC converter configured to receive an output voltage compensated for by the temperature compensation unit and convert the received output voltage into a digital voltage signal. The neuron circuit also includes an activation function unit configured to apply an activation function of a neuron to the digital voltage signal. The neuron circuit further includes a pulse generator configured to output a voltage signal to be transferred to the another resistive memory array.

Next, in accordance with an embodiment of the present disclosure, a neuromorphic hardware apparatus based on a resistive memory array includes a resistive memory array in which a plurality of synaptic resistor elements are arranged. Each synaptic resistor element is changed in its resistance value depending on a voltage pulse applied thereto and stores the resistance value for a predetermined time. The neuromorphic hardware apparatus also includes a neuron circuit configured to receive an output signal from the resistive memory array and output a voltage signal to another resistive memory array. The neuromorphic hardware apparatus also includes a temperature compensation unit connected to the resistive memory array. The temperature compensation unit is configured to compensate for an output voltage of the resistive memory array on the basis of an operating temperature of the resistive memory array and input the compensated output voltage to the neuron circuit.

In addition, the resistive memory array is arranged in the form of a crossbar array, and the temperature compensation unit is connected to an output terminal of each column of the resistive memory array.

Here, the temperature compensation unit includes a transimpedance amplifier (TIA), which performs amplification by converting a current signal into a voltage signal.

In addition, a feedback resistor of the transimpedance amplifier is an element which has the same property as operating property of the resistive memory array depending on a temperature, by having a value according to the following equation.

$${R}_{F} ( T ) = \frac{{R}_{0}}{α ( T )}$$

In this equation, R_{F}(T) is a feedback resistance value at the operating temperature, Rₒ is an initial resistance value of the feedback resistor at a room temperature, and α(T) is a set value based on operating temperature data of the feedback resistor.

Meanwhile, the neuron circuit includes an ADC converter configured to receive an output voltage compensated for by the temperature compensation unit and convert the received output voltage into a digital voltage signal. The neuron circuit also includes an activation function unit configured to apply an activation function of a neuron to the digital voltage signal. The neuron circuit also includes a pulse generator configured to output a voltage signal to be transferred to the another resistive memory array.

According to the present disclosure, even when an abnormal output is outputted by a resistive memory array depending on an operating temperature, the abnormal output is compensated for and the compensated output current is inputted to the neuron circuit. Thus, it is possible to prevent an operation error of the neuron circuit from occurring, thereby enabling a stable network operation.

In other words, the output of the neural circuit may be constantly maintained even when an output current of the resistive memory array varies.

Therefore, through this, it is possible to maintain the learning accuracy of an artificial neural network.

### BRIEF DESCRIPTION OF THE DRAWINGS

FIG. 1 is a diagram schematically illustrating neuron circuits, which configure a hardware apparatus of the present disclosure.

FIG. 2 is a diagram schematically illustrating the configuration of current sensing circuits of FIG. 1.

FIG. 3 is a diagram illustrating a measured value Mea. in which a conductance G of a resistive element follows the Arrhenius equation depending on a temperature.

FIG. 4 is a cumulative probability graph for conductance, depending on a temperature variation, of resistive elements having a specific resistance value in an array as shown, illustrating simulation data obtained by applying a temperature variation model measured in a single element.

FIG. 5 is a diagram showing that the distribution of a current as the output of a resistive memory array abnormally increases depending on a variation in operating temperature.

FIGS. 6 and 7 are diagrams illustrating transmission paths of output currents of resistive memory arrays.

FIG. 8 is a diagram illustrating a resistive memory array and a temperature compensation unit according to an embodiment of the present disclosure.

FIG. 9 is a diagram illustrating an array output current, which abnormally increases, and illustrating a feedback resistance value, which is adjusted depending on a temperature.

FIG. 10 is a diagram comparing operations of 10 output layer neurons when a specific MNIST handwritten image is inputted to a hardware neural network.

FIG. 11 is a graph illustrating the cumulative distribution function of the operations of neurons for 100 test image inputs.

FIG. 12 is a graph comparing the accuracies of entire neuromorphic hardware depending on a temperature.

### DESCRIPTION OF SPECIFIC EMBODIMENTS

In order to fully understand the present disclosure and operational advantages of the present disclosure and objects attained by practicing the present disclosure, reference should be made to the accompanying drawings that illustrate embodiments of the present disclosure and to the description in the accompanying drawings. When a component, device, element, or the like of the present disclosure is described as having a purpose or performing an operation, function, or the like, the component, device, or element should be considered herein as being “configured to” meet that purpose or to perform that operation or function.

In describing embodiments of the present disclosure, known technologies or repeated descriptions may be reduced or omitted to avoid unnecessarily obscuring the gist of the present disclosure.

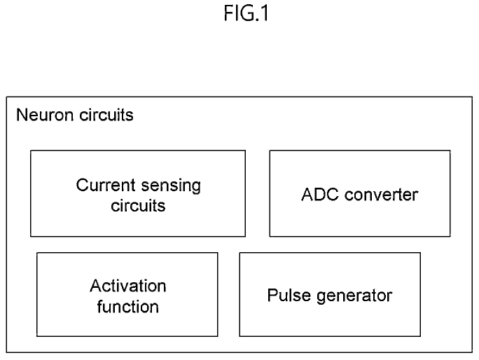

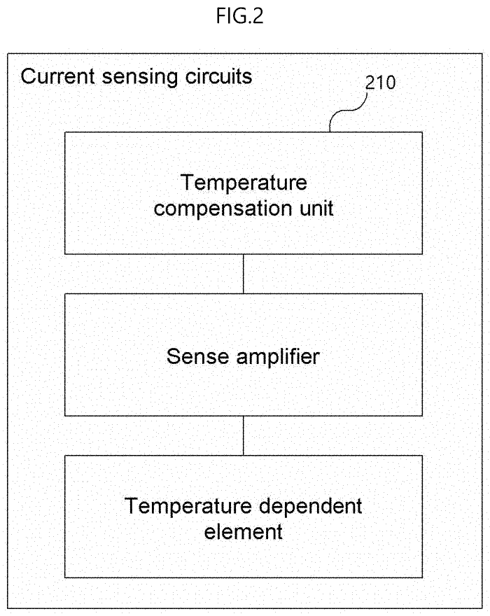

FIG. 1 is a diagram schematically illustrating neuron circuits, which configure a hardware apparatus of the present disclosure. FIG. 2 is a diagram schematically illustrating the configuration of current sensing circuits of FIG. 1 and FIGS. 6 and 7 are diagrams illustrating transmission paths of output currents of resistive memory arrays.

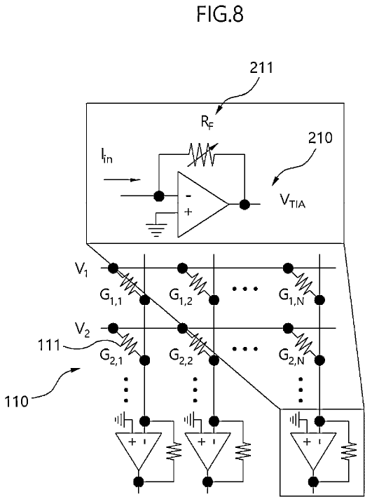

FIG. 8 is a diagram illustrating a resistive memory array and a temperature compensation unit according to an embodiment of the present disclosure.

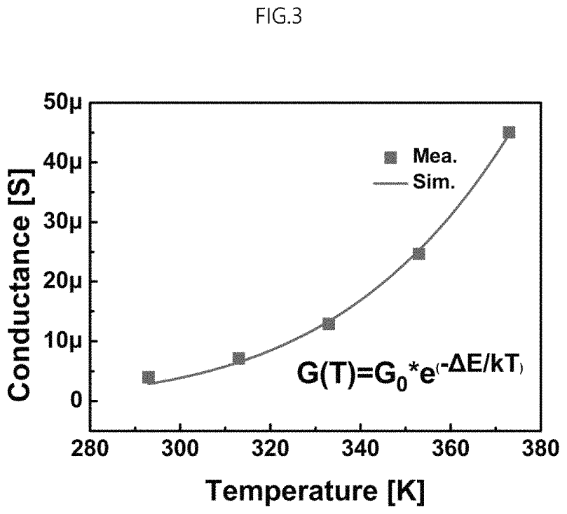

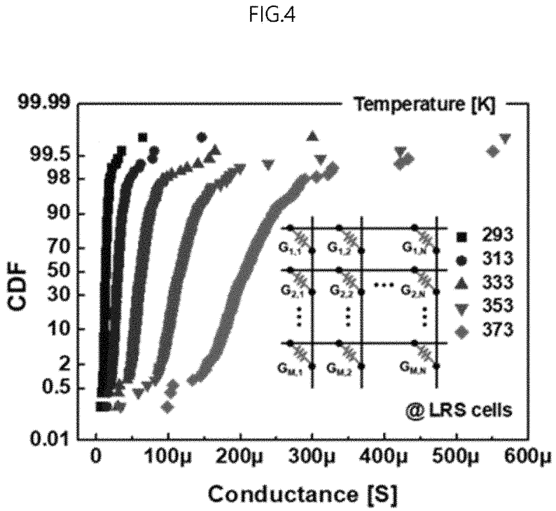

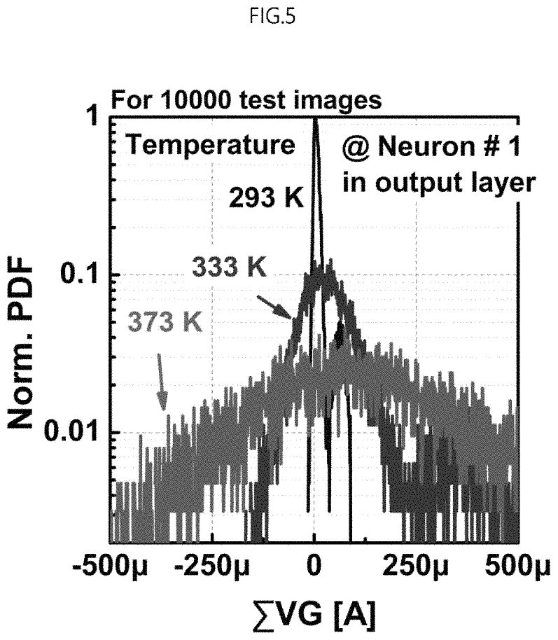

Hereinafter, a neuromorphic hardware apparatus based on a resistive memory array according to an embodiment of the present disclosure is described with reference to FIGS. 1-8.

The neuromorphic hardware apparatus based on a resistive memory array of the present disclosure configures an artificial neural network for machine learning and comprises neuron circuits and a resistive memory array serving as a synapse element, which connects the neuron circuits.

The neuron circuit receives a current signal from the resistive memory array, converts the current signal into a digital voltage signal, and, after activation processing, outputs a voltage signal to a next resistive memory array.

In other words, as shown in FIG. 1, the neuron circuit converts an input current into a digital voltage signal by an ADC converter, applies an activation function of a neuron to the converted digital voltage signal in an activation function unit, and outputs a voltage signal to be transferred to a next resistive memory array in a pulse generator.

A resistive memory array 110, as shown in FIG. 8, comprises a plurality of rows and a plurality of columns in the form of a crossbar array. The resistive memory array 110 generates a current by performing matrix-vector multiplication (MVM) by an applied voltage and transfers the generated current to the neuron circuit.

In the resistive memory array 110 in the form of a crossbar array, a plurality of synaptic resistor element 111 are coupled and arranged between row lines and column lines. Each synaptic resistor element 111 is an element whose resistance value linearly varies depending on an applied voltage and each synaptic resistor element 111 has a property of storing the resistance value for a predetermined time.

However, the conductance of the synaptic resistor element 111 varies depending on an operating temperature and an output current value varies depending on the varied conductance.

In this way, when an output current is abnormally generated, the artificial neural network cannot be stably operated.

In order to cope with this problem, the neuron circuits of the present disclosure include current sensing circuits and each current sensing circuit includes a temperature compensation unit 210. The temperature compensation unit 210 compensates for an output current depending on a temperature and inputs the compensated output current to the neuron circuit.

The temperature compensation unit 210 may be configured between the neuron circuit and the resistive memory array 110, separately from the neuron circuit.

The current sensing circuit includes the temperature compensation unit 210, a sense amplifier, and a temperature dependent element.

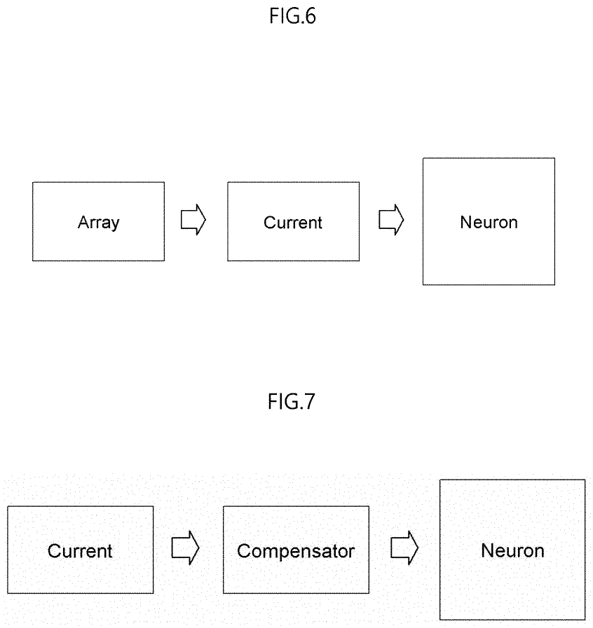

Therefore, in contrast to that a current from a resistive memory array 110 is inputted to a neuron circuit as shown in FIG. 6, a current is compensated for by the temperature compensation unit 210 and the compensated current is inputted to a neuron circuit as shown in FIG. 7.

When a current signal is converted into a voltage signal, the sense amplifier functions to regulate the amplification of a signal by adjusting a gain.

The temperature dependent element is an element whose conductance varies depending on a temperature and thus the temperature dependent element may sense the degree of a temperature variation.

The temperature compensation unit 210 is connected to each column of the resistive memory array 110 as shown in FIG. 8. The temperature compensation unit 210 may be a transimpedance amplifier (TIA)-current to voltage converter, which performs amplification by converting a current signal into a voltage signal. The temperature compensation unit 210 automatically adjusts a resistance value of the resistive memory array 110 by a feedback resistor R_{F} depending on a temperature variation, so as to compensate for an output voltage.

In more detail, a conductance G of the synaptic resistor element 111 varies in proportion to α(T) depending on a temperature as in Equation 1.

G(T)=G₀·α(T) [Equation 1]

An output current I(T) by the temperature compensation unit 210 is as follows.

I(T)=ΣVG(T)=α(T)ΣVG₀ [Equation 2]

When the feedback resistor 211 is set as in the following Equation 3, an output voltage V_{TIA}(T) by the temperature compensation unit 210 is outputted regardless of α(T), as in Equation 4.

$${R}_{F} ( T ) = \frac{{R}_{0}}{α ( T )} \qquad [ Equation 3 ]$$

Here, Rₒ is a total resistance value of each column of a resistive memory array 110, R_{F} varies depending on a, and a is a set value based on operating temperature data of the resistive memory array 110.

V_{TIA}(T)=R_{F}(T)×ΣVG(T)=R₀ΣVG₀ [Equation 4]

Namely, based on an element having temperature dependence of reaction such as the synaptic resistor element 111, output is performed as the output voltage V_{TIA}(T) is amplified by the reciprocal term of α(T) in the transimpedance amplifier.

As such, when the conductance G of the synaptic resistor element 111 in the resistive memory array 110 is changed by α(T) times an existing conductance Go, an output current of a specific line of the resistive memory array 110 is also changed by α(T) times an existing output current Iₒ. In this way, the temperature compensation unit 210 compensates for an abnormal output current of the resistive memory array 110, by amplifying or scaling the abnormal output current by 1/α(T) before the abnormal output current is inputted to a neuron circuit. Accordingly, an output voltage is stably outputted without being affected by a temperature and is normally transferred to the neuron circuit.

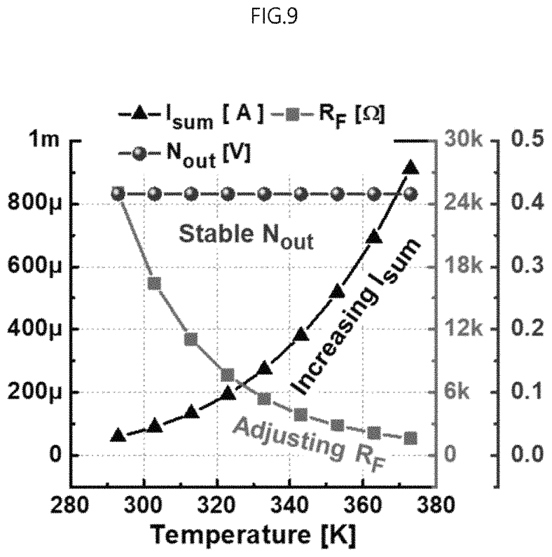

FIGS. 9-12 show simulation results compared with a case where there is no temperature compensation unit, in order to verify the effect of the temperature compensation unit 210. Through these simulation results, it may be seen that, even when a temperature rises, a network stably operates as in an operation under a room temperature.

FIG. 9 is a diagram illustrating an array output current, which abnormally increases, and illustrating a feedback resistance value, which is adjusted depending on a temperature. It may be seen that by a resultant compensation effect, an output (blue) of a neuron is constantly maintained depending on a temperature.

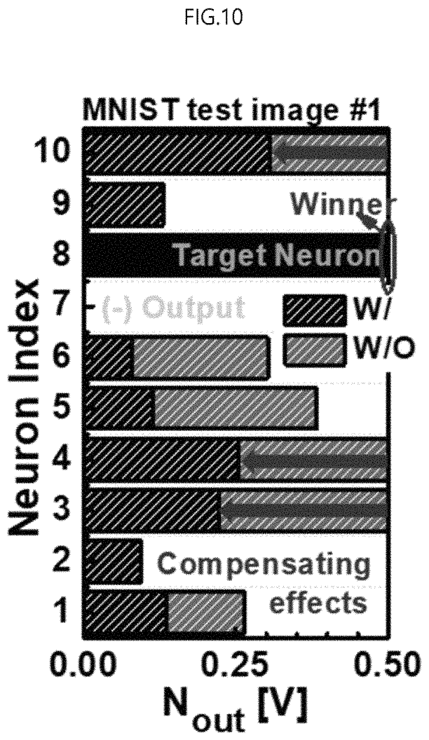

FIG. 10 is a diagram comparing operations of 10 output layer neurons when a specific MNIST handwritten image is inputted to a hardware neural network. It may be seen that outputs, when there is no temperature compensation unit, do not recognize a correct answer. By contrast, outputs, when there is a temperature compensation unit 210, recognize the signal of a neuron numbered 8 as a strongest correct answer.

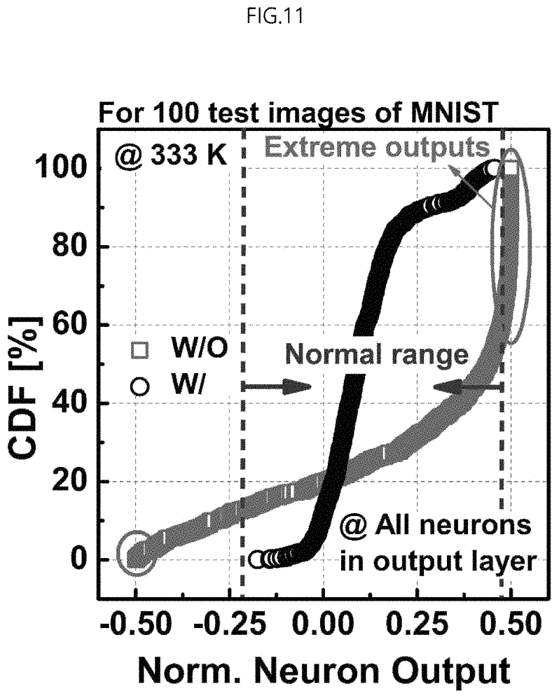

FIG. 11 is a graph illustrating the cumulative distribution function of the operations of neurons for 100 test image inputs. It may be seen that, even when a temperature rises, the output of a neuron operates in a normal region due to the effect of the temperature compensation unit 210.

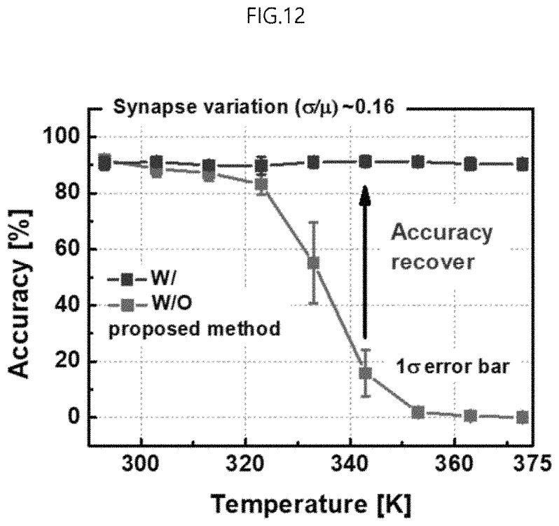

FIG. 12 is a graph comparing the accuracies of entire neuromorphic hardware depending on a temperature. It may be seen that an accuracy rapidly decreases depending on a temperature when there is no temperature compensation unit but an accuracy is maintained even when a temperature rises when there is a temperature compensation unit 210.

As is apparent from the above description, according to the neuromorphic hardware apparatus based on a resistive memory array 110 of the present disclosure, even when a resistive memory array 110 outputs an abnormal output depending on an operating temperature, by compensating a neuron circuit for an input value, it is possible to prevent an operation error from occurring. This results in a stable operation of an artificial neural network.

While the present disclosure has been described with reference to the accompanying drawings, it should be apparent to those having ordinary skill in the art that various changes and modifications can be made without departing from the spirit and scope of the present disclosure without being limited to the embodiments disclosed herein. Accordingly, it should be noted that such alternations or modifications fall within the claims of the present disclosure, and the scope of the present disclosure should be construed on the basis of the appended claims.

What is claimed is:

1. A neuromorphic hardware apparatus based on a resistive memory array, the neuromorphic hardware apparatus comprising:
a resistive memory array in which a plurality of synaptic resistor elements are arranged, each synaptic resistor element being changed in its resistance value depending on a voltage pulse applied thereto and storing the resistance value for a predetermined time; and
a neuron circuit configured to receive an output signal from the resistive memory array and output a voltage signal to another resistive memory array,
wherein the neuron circuit includes a temperature compensation unit, which compensates for an output voltage of the resistive memory array on the basis of an operating temperature of the resistive memory array.

2. The neuromorphic hardware apparatus of claim 1, wherein the resistive memory array is arranged in the form of a crossbar array, and the temperature compensation unit is connected to an output terminal of each column of the resistive memory array.

3. The neuromorphic hardware apparatus of claim 2, wherein the temperature compensation unit includes a transimpedance amplifier (TIA) which performs amplification by converting a current signal into a voltage signal.

4. The neuromorphic hardware apparatus of claim 3, wherein a feedback resistor of the transimpedance amplifier is an element, which has the same property as operating property of the resistive memory array depending on a temperature, by having a value according to the following equation:
$${R}_{F} ( T ) = \frac{{R}_{0}}{α ( T )}$$
where R_{F}(T) is a feedback resistance value at the operating temperature, Rₒ is an initial resistance value of the feedback resistor at a room temperature, and α(T) is a set value based on operating temperature data of the feedback resistor.

5. The neuromorphic hardware apparatus of claim 4, wherein the neuron circuit comprises:
an ADC converter configured to receive an output voltage compensated for by the temperature compensation unit and convert the received output voltage into a digital voltage signal;
an activation function unit configured to apply an activation function of a neuron to the digital voltage signal; and
a pulse generator configured to output a voltage signal to be transferred to the another resistive memory array.

6. A neuromorphic hardware apparatus based on a resistive memory array, the neuromorphic hardware apparatus comprising:
a resistive memory array in which a plurality of synaptic resistor elements are arranged, each synaptic resistor element being changed in its resistance value depending on a voltage pulse applied thereto and storing the resistance value for a predetermined time;
a neuron circuit configured to receive an output signal from the resistive memory array and output a voltage signal to another resistive memory array; and
a temperature compensation unit connected to the resistive memory array and configured to compensate for an output voltage of the resistive memory array on the basis of an operating temperature of the resistive memory array and input the compensated output voltage to the neuron circuit.

7. The neuromorphic hardware apparatus of claim 6, wherein the resistive memory array is arranged in the form of a crossbar array, and the temperature compensation unit is connected to an output terminal of each column of the resistive memory array.

8. The neuromorphic hardware apparatus of claim 7, wherein the temperature compensation unit includes a transimpedance amplifier (TIA), which performs amplification by converting a current signal into a voltage signal.

9. The neuromorphic hardware apparatus of claim 8, wherein a feedback resistor of the transimpedance amplifier is an element, which has the same property as operating property of the resistive memory array depending on a temperature, by having a value according to the following equation:
$${R}_{F} ( T ) = \frac{{R}_{0}}{α ( T )}$$
where R_{F}(T) is a feedback resistance value at the operating temperature, Rₒ is an initial resistance value of the feedback resistor at a room temperature, and α(T) is a set value based on operating temperature data of the feedback resistor.

10. The neuromorphic hardware apparatus of claim 9, wherein the neuron circuit comprises:
an ADC converter configured to receive an output voltage compensated for by the temperature compensation unit and convert the received output voltage into a digital voltage signal;
an activation function unit configured to apply an activation function of a neuron to the digital voltage signal; and
a pulse generator configured to output a voltage signal to be transferred to the another resistive memory array.
